(19) United States
(12) Patent Application Publication
(10) Pub. No.: US 2024/0142884 A1
(43) Pub. Date: May 2, 2024

(54) IMAGE BASED OVERLAY MARK AND IMAGE BASED OVERLAY MEASURING METHOD USING THE SAME

(71) Applicant: SK hynix Inc., Icheon-si (KR)

(72) Inventor: Joon Seuk LEE, Icheon-si (KR)

(21) Appl. No.: 18/336,308

(22) Filed: Jun. 16, 2023

(30) Foreign Application Priority Data
Nov. 2, 2022 (KR) 10-2022-0144305

(51) Int. Cl. G03F 7/20; G03F 7/00

(52) U.S. Cl. CPC G03F 7/70633; G03F 7/70683; G03F 7/706849

(57) ABSTRACT

An image based overlay measuring method may include an overlay mark preparation step, an overlay signal generation step and an overlay measuring step. The overlay mark preparation step may include preparing an image based overlay mark including a lower pattern and an upper pattern. The lower pattern and the upper pattern may have an overlapped portion from a planar view. The overlay signal generation step may include generating a lower overlay signal from a lower non-overlapped region of the lower pattern and an upper overlay signal from an upper non-overlapped region of the upper pattern using image information of the image based overlay mark. The overlay measuring step may include comparing the lower overlay signal with the upper overlay signal to measure an overlay.

### CROSS-REFERENCES TO RELATED APPLICATION

The present application claims priority under 35 U.S.C. § 119(a) to Korean application number 10-2022-0144305, filed on Nov. 2, 2022, in the Korean Intellectual Property Office, which is incorporated herein by reference in its entirety.

### BACKGROUND

### 1. Technical Field

Various embodiments generally relate to an image based overlay mark and an image based overlay measuring method using the same, and more particularly, to an image based overlay mark having improved structure and process and an image based overlay measuring method using the overlay mark.

### 2. Related Art

A semiconductor device may be formed by forming a plurality of layers on a substrate. A relative position of the layers may have influence on the performance of the semiconductor device, and therefore control of the relative position of the layers is required. An overlay related to the semiconductor layers may be measured using an overlay mark.

The overlay measuring method may be classified into a diffraction based overlay measuring method based on a diffraction of the overlay mark and an image based overlay measuring method using an image(s) of the overlay mark(s).

The diffraction based overlay measuring method may include measuring an overlay of the overlay mark using the diffraction of the overlay mark. The overlay mark includes a lower pattern and an upper pattern, which are offset from each other. The overlay may be measured by a degree of misalignment of the lower pattern and an upper pattern. The diffraction based overlay measuring method may have high accuracy, but may be performed at a lower speed.

The image based overlay measuring method may include obtaining images of the upper pattern and the lower pattern of the overlay mark, and comparing relative positions of the upper pattern and the lower pattern through the obtained images. The amount of overlay of the overlay mark is measured using a comparison result. The image based overlay measuring method can be performed more rapidly, but may have low accuracy.

In the related art, from a plan view, the upper pattern and the lower pattern in the image based overlay mark might not overlap with each other enough to accurately recognize the upper pattern and the lower pattern from the image information. That is, a first region in which the upper pattern may be positioned may be separated from a second region in which the lower pattern may be positioned. Thus, the lower pattern might not be positioned in the first region. In contrast, the upper pattern might not be positioned in the second region. In addition, the first region and the second region may have different pattern densities so that process errors such as an asymmetry, a deformation of the lower pattern, erosion, a dishing, etc., may be generated in various processes such as a patterning process, an etching process, a CMP process, etc. As a result, the overlay measuring may have low accuracy.

### SUMMARY

According to example embodiments, there may be provided an image based overlay measuring method. The image based overlay measuring method may include an overlay mark preparation step, an overlay signal generation step and an overlay measuring step. The overlay mark preparation step may include preparing an image based overlay mark including a lower pattern and an upper pattern. The lower pattern and the upper pattern may have an overlapped portion from a planar view. The overlay signal generation step may include generating a lower overlay signal from a lower non-overlapped region of the lower pattern and an upper overlay signal from an upper non-overlapped region of the upper pattern using image information of the image based overlay mark. The overlay measuring step may include comparing the lower overlay signal with the upper overlay signal to measure an overlay.

According to example embodiments, there may be provided an image based overlay measuring method. The image based overlay measuring method may include an overlay mark preparation step, an overlay signal generation step and an overlay measuring step. The overlay mark preparation step may include preparing an image based overlay mark including a lower pattern and an upper pattern. The lower pattern and the upper pattern may have an overlapped portion from a planar view. The overlay signal generation step may include generating a lower overlay signal from lower image information, which may be obtained by focusing on the lower pattern, an upper overlay signal from upper image information, which may be obtained by focusing on the upper pattern. The overlay measuring step may include comparing the lower overlay signal with the upper overlay signal to measure an overlay.

According to example embodiments, there may be provided an image based overlay mark used for measuring an overlay using image information. The image based overlay mark may include a first region and a second region having different pattern arrangements. The image based overlay mark may include a lower pattern and an upper pattern having an overlapped portion from a planar view. The lower pattern may include a plurality of first lower patterns and a plurality of second lower patterns. The first lower patterns may be extended along a first direction in the first region. The second lower patterns may be extended along a second direction intersected with the first direction in the second region. The upper pattern may include a plurality of first upper patterns and a plurality of second upper patterns. The first upper patterns may be extended along the first direction in the second region. The second upper patterns may be extended along the second direction in the first region.

According to the image based overlay mark of example embodiments, the lower pattern and the upper pattern may be provided together to the all regions so that the overlay mark may have a uniform large pattern density to effectively prevent a process error in various processes after forming the lower pattern. Further, numbers of patterns used in measuring the overlay may be increased to improve accuracy of the overlay measuring.

According to the image based overlay measuring method of example embodiments, although the overlapped portion may be formed between the lower and upper patterns, the lower and upper overlay signals may be stably generated using the non-overlapped portion to measure the overlay from the upper and lower overlay signals. For example, a process may be simplified using a common focus way to decrease a process time. Alternatively, an influence by the overlapped portion may be minimized using a dual focus way to improve the accuracy of the overlay measuring. When first and second detector may be used together with each other, the overlay signal may be rapidly generated in the dual focus way.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a plan view illustrating an image based overlay mark in accordance with example embodiments of the disclosure;

FIGS. 2A and 2B are plan views illustrating a lower pattern and an upper pattern of an image based overlay mark in accordance with example embodiments of the disclosure;

FIG. 3 is a cross-sectional view taken along a line III-III′ in FIG. 1;

FIG. 4 is a plan view illustrating an image based overlay mark in accordance with example embodiments of the disclosure;

FIG. 5 is a plan view illustrating an image based overlay mark in accordance with example embodiments of the disclosure;

FIG. 6 is a plan view illustrating an image based overlay mark in accordance with example embodiments of the disclosure;

FIG. 7 is a view illustrating an image based overlay measuring apparatus configured to perform an image based overlay measuring method in accordance with example embodiments of the disclosure;

FIG. 8 is a flow chart illustrating an image based overlay measuring method in accordance with example embodiments of the disclosure;

FIG. 9 is a view illustrating an overlay signal generation step in the image based overlay measuring method in FIG. 8;

FIG. 10 is a view illustrating an image based overlay measuring apparatus configured to perform an image based overlay measuring method in accordance with example embodiments of the disclosure;

FIG. 11 is a flow chart illustrating an image based overlay measuring method in accordance with example embodiments of the disclosure;

FIGS. 12A and 12B are a view illustrating an overlay signal generation step in the image based overlay measuring method in FIG. 11;

FIG. 13 is a view illustrating an image based overlay measuring apparatus configured to perform an image based overlay measuring method in accordance with example embodiments of the disclosure; and

FIGS. 14A and 14B are a flow chart illustrating an overlay signal generation step in an image based overlay measuring method in accordance with example embodiments of the disclosure.

### DETAILED DESCRIPTION

Various embodiments of the present disclosure will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes, which do not depart from the spirit and scope of the present invention as defined in the appended claims.

The present invention is described herein with reference to cross-section and/or plan illustrations of idealized embodiments of the present invention. However, embodiments of the present invention should not be construed as limiting the inventive concepts. Although a few embodiments of the present invention will be shown and described, it will be appreciated by those of ordinary skill in the art that changes may be made in these embodiments without departing from the principles and spirit of the present invention.

Hereinafter, an image based overlay mark (hereinafter, referred to as an overlay mark) and an image based overlay measuring method (hereinafter, referred to as an overlay measuring method) may be illustrated in detail.

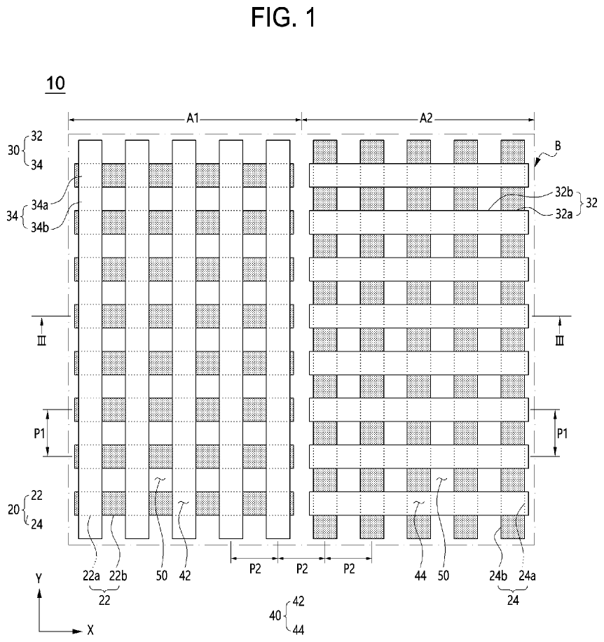

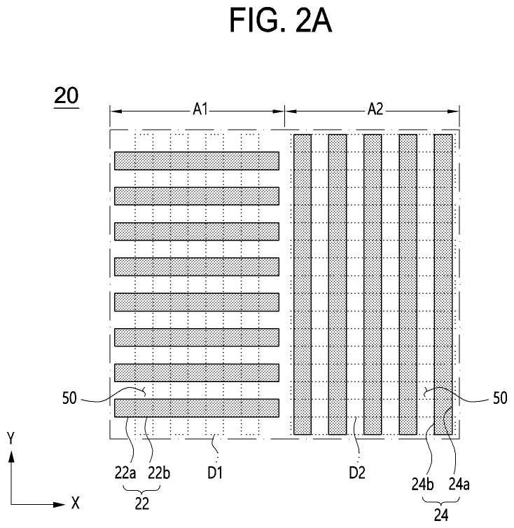

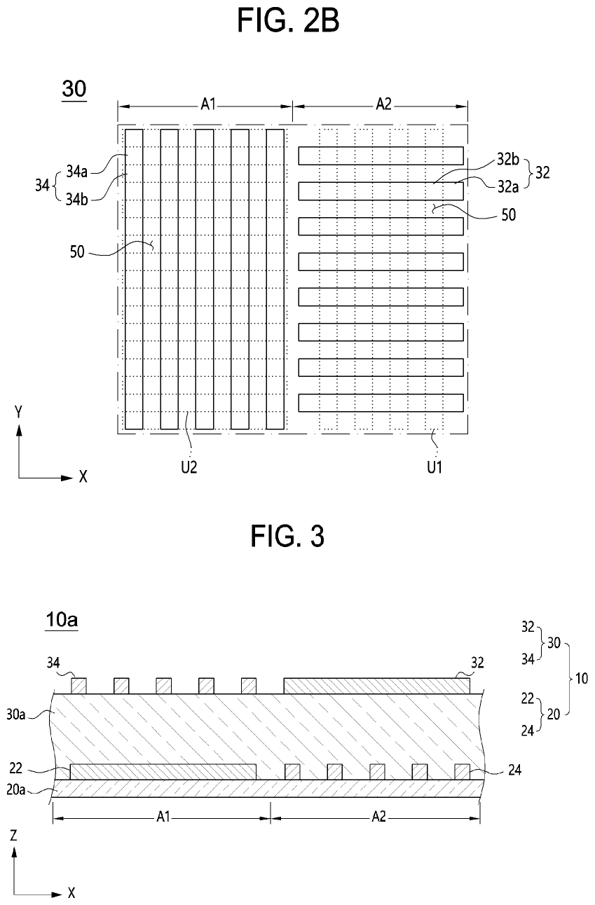

FIG. 1 is a plan view illustrating an image based overlay mark in accordance with example embodiments of the disclosure. FIGS. 2A and 2B are plan views illustrating a lower pattern and an upper pattern of an image based overlay mark in accordance with example embodiments of the disclosure. FIG. 3 is a cross-sectional view taken along a line III-III′ in FIG. 1. In FIGS. 1 to 3, the upper pattern and the lower pattern of the overlay mark are mainly depicted. Other layer directly related to example embodiments may be omitted herein for brevity.

Referring to FIGS. 1 to 3, an overlay mark 10 of example embodiments may be used for measuring an overlay using image information. The overlay mark 10 may have a first region A1 and a second region A2 having different pattern arrangements. The overlay mark 10 may include at least one lower pattern 20 and at least one upper pattern 30. From a planar view, an overlapped portion 40 is divided into the first region A1 and the second region A2. The lower pattern 20 may include lower non-overlapped portions 22b and 24b in each of the first region A1 and the second region A2, respectively, and upper non-overlapped portions 34b and 32b in each of the first region A1 and the second region A2, respectively.

The overlay mark 10 may be used for recognizing an alignment between the lower pattern 20 and the upper pattern 30. For example, the overlay mark 10 may be used for recognizing the alignment of stacked layers. The overlay mark 10 may be formed in a scribe region, such as, a scribe lane.

Referring to FIG. 3, in the overlay mark 10, the lower pattern 20 may be formed on a lower structure 20a. The lower pattern 20 may include a material substantially the same as a material of a lower layer used for recognizing the alignment. For example, the lower pattern 20 may include a metal layer, a semiconductor layer, an insulation layer, etc. The upper pattern 30 may be formed on an upper structure 30a configured to cover the lower structure 20a and the lower pattern 20. For example, the upper pattern 30 may include a photoresist pattern. For example, the lower structure 20a may include a semiconductor substrate such as a wafer. A structure 10a with the overlay mark 10 may include a semiconductor device. The upper structure 30a may include an insulation layer, a semiconductor layer, a metal layer, etc. Embodiments of the disclosure, however, are not so limited and the upper structure 30a may include a single layer or a multi-layer. Thus, the structures and the materials of the lower structure 20a, the upper structure 30a, the lower pattern 20 and the upper pattern 30 may be variously changed. Further, the structure 10a with the overlay mark 10 may also be variously changed.

As shown in FIG. 2A, the lower pattern 20 may include a plurality of first lower patterns 22 and a plurality of second lower patterns 24. The first lower patterns 22 may be extended along a first direction (an X-direction) in the first region A1. The second lower patterns 24 may be extended along a second direction (Y-direction) in the second region A2. Thus in FIG. 2A, the first lower patterns 22 may be crossed to the second lower patterns 24.

As shown in FIG. 2B, the upper pattern 30 may include a plurality of first upper patterns 32 and a plurality of second upper patterns 34. The first upper pattern 32 may be extended along the first direction in the second region A2. The second upper patterns 34 may be extended along the second direction in the first region A1.

A plurality of first overlapped portions 42 between the first lower patterns 22 and the second upper patterns 34 may be formed in the first region A1. A plurality of second overlapped portions 44 between the second lower patterns 24 and the first upper patterns 32 may be formed in the second region A2. That is, the overlapped portion 40 may include the first overlapped portions 42 in the first region A1 and the second overlapped portions 44 in the second region A2.

When the lower pattern 20 includes the intersected first and second lower patterns 22 and 24 and the upper pattern 30 includes the intersected first and second upper patterns 32 and 34, the overlay may be measured in the first and second directions to obtain an accurate overlay.

In example embodiments, the first region A1 and the second region A2 may have different pattern arrangements. The lower pattern 20 and the upper pattern 30 in the first region A1 may have a regular shape and arrangement. The lower pattern 20 and the upper pattern 30 in the second region A2 may have a regular shape and arrangement. In other embodiments, the shape and the arrangement of the lower pattern 20 and the upper pattern 30 in the first region A1 may be different from the shape and the arrangement of the lower pattern 20 and the upper pattern 30 in the second region A2.

Particularly, the first lower patterns 22 in the first region A1 may include a plurality of first lower overlapped portions 22a and a plurality of first lower non-overlapped portions 22b. The first overlapped portions 42 may be formed of the first overlapped portions 22a. The first lower non-overlapped portions 22b may be positioned in a region of the first lower patterns 22 except for the first overlapped portions 42. The first lower overlapped portions 22a and the first lower non-overlapped portions 22b in one first lower pattern 22 may be alternately arranged in the first direction. The first lower patterns 22 may be spaced apart from each other in the second direction by a first pitch P1.

The second lower patterns 24 in the second region A2 may include a plurality of second lower overlapped portions 24a and a plurality of second lower non-overlapped portions 24b. The second overlapped portions 44 may be formed of the second lower overlapped portions 24a. The second lower non-overlapped portions 24b may be positioned in a region of the second lower patterns 24 except for the second overlapped portions 44. The second lower overlapped portions 24a and the second lower non-overlapped portions 24b in one second lower pattern 24 may be alternately arranged in the second direction. The second lower patterns 24 may be spaced apart from each other in the first direction by a second pitch P2.

The first upper patterns 32 in the second region A2 may include a plurality of first upper overlapped portions 32a and a plurality of first upper non-overlapped portions 32b. The second overlapped portions 44 may be formed of the first upper overlapped portions 32a. The first upper non-overlapped portions 32b may be positioned in a region of the first upper patterns 32 except for the second overlapped portions 44. The first upper overlapped portions 32a and the first upper non-overlapped portions 32b in one first upper pattern 32 may be alternately arranged in the first direction. The first upper patterns 32 may be spaced apart from each other in the second direction by the first pitch P1.

The second upper patterns 34 in the first region A1 may include a plurality of second upper overlapped portions 34a and a plurality of second upper non-overlapped portions 34b. The first overlapped portions 42 may be formed of the second upper overlapped portions 34a. The second upper non-overlapped portions 34b may be positioned in a region of the second upper patterns 34 except for the first overlapped portions 42. The second upper overlapped portions 34a and the second upper non-overlapped portions 34b in one second upper pattern 34 may be alternately arranged in the second direction. The second upper patterns 34 may be spaced apart from each other in the first direction by the second pitch P2.

As described above, the overlay mark 10 may be the image based overlay mark configured to measure the overlay by comparing a relative position between the lower pattern 20 and the upper pattern 30 using the image information. Thus, because the overlay mark 10 may be images, the overlay mark 10 might not include features required in a diffraction based overlay mark.

For example, in order to measure the overlay using a diffraction based overlay mark, at least one lower pattern 20 and at least one upper pattern 30 may be extended in a same direction. The lower pattern and the upper pattern may be positioned at offset positions. That is, the upper pattern and the lower pattern may be shifted from each other by a set distance, for example, 20 nm. According to image information of the upper pattern and the lower pattern, the upper pattern and the lower pattern may have different colors. Thus, the diffraction based overlay mark is distinguished from the image based overlay mark 10 of example embodiments, which uses an overlay measuring apparatus.

In example embodiments, because the overlay mark 10 may be the image based overlay mark, the lower pattern 20 and the upper pattern 30 may be uniformly spaced apart from each other without an offset from a plan view.

Particularly, from a plan view, the first lower patterns 22 and the first upper patterns 32 both extend in the first direction and may be spaced apart from each other in the second direction by the uniform gap or pitch, without an offset. That is, the overlay of the overlay marks of the first region A1 and the overlay of the overlay marks of the second region A2 may be within a set distance. The uniform gap without an offset may mean that the gap may be below the set distance, for example, 0.1 nm to 20 nm. For example, the first lower patterns 22 and the first upper patterns 32 may be arranged to correspond to each other on same rows, from a plan view. The first lower patterns 22 and/or the first upper patterns 32 may be spaced apart from each other by the same first pitch P1 in the second direction.

In FIG. 1, the first lower pattern 22 in the first region A1 may be spaced apart from the first upper pattern 32 in the second region A2 along the first direction to prevent the accuracy of the overlay measuring from being decreased due to interference between the first lower pattern 22 and the first upper pattern 32. Alternatively, at least one first lower pattern 22 in the first region A1 may be adjacent to at least one first upper pattern 32 in the second region A2 along the first direction. In other words, one ends of the first lower patterns 22 in the first region A1 may be overlapped with the other ends of the first upper patterns 32 in the second regions A2.

The second lower patterns 24 and the second upper patterns 34 extended in the second direction may be spaced apart from each other by a uniform gap or pitch along the first direction without an offset. That is, a pitch between the second lower patterns 24, between the second upper patterns 34, and between the second lower pattern 24 and the second upper pattern adjacent to each other at a boundary between the first region A1 and the second region A2 may be the same second pitch P2.

Alternatively, in the overlay mark 10 of example embodiments, the first pitch P1 or the second pitch P2 may be different from an offset required by ae diffraction based overlay mark. That is, the first pitch P1 or the second pitch P2 of the overlay mark 10 may be greater than that of a diffraction based overlay mark. The diffraction based overlay mark may collect primary light to measure the overlay. When the pitch is large, a high-ordered light (ex. nth light) may be collected together with the primary light, which creates a measurement problem. Thus, the diffraction based overlay mark may have a relatively low pitch. In contrast, in the overlay mark 10 of example embodiments such as the image based overlay mark, the first pitch P1 or the second pitch P2 may be large enough to stably recognize, visually, the shape of the pattern on the image information.

For example, the first pitch P1 and/or the second pitch P2 may be no less than about 800 nm, or for example, about 1 μm. Embodiments are not limited thereto. The first pitch P1 or the second pitch P2 may be variously changed.

The overlay mark 10 of example embodiments such as the image based overlay mark may be readily distinguished from the diffraction based overlay mark in other ways.

In the overlay mark 10 of example embodiments, the lower patterns 20 and the upper patterns 30 may be arranged in the first region A1 and the second region A2. Thus, the lower pattern 20 and the upper pattern 30 may be formed together in the first region A1 and the second region A2, respectively. When a portion of the overlay mark 10 having regular pattern arrangements may be defined in a region. The region may include both of the plurality of lower patterns 20 and the plurality of upper patterns 30. That is, at least one overlay mark 10 including the lower pattern 20 and the upper pattern 30 may be arranged in the region in a manner that creates overlapped portions and non-overlapped portions in the same region.

Therefore, the pattern density of the lower pattern 20 and the upper pattern 30 may be increased to increase pattern density in a region where a pattern may not be formed. Thus, the overlay mark 10 may be slightly affected by various processes performed after forming the lower pattern 20, such as a patterning process, an etching process, a CMP process, etc., to effectively prevent process errors such as erosion, dishing, etc., generated in the processes. Further, total numbers of the lower pattern 20 and the upper pattern 30 used for the overlay measuring may be increased to improve the accuracy of the overlay measuring.

In contrast, in a conventional image based overlay mark, lower patterns and upper patterns may not be overlapped with each other but formed on a same plane. Thus, a difference between a density of the lower patterns and a density of the upper patterns may be generated in a measuring region including the conventional image based overlay mark. The process errors such as the erosion, the dishing, etc., may be caused by the difference between the pattern densities in the processes performed after forming the lower pattern. Further, numbers of rows or columns of the pattern used for the overlay measuring may be restricted because the lower pattern and the upper pattern may not be overlapped with each other in a region so that the overlay measuring may have low accuracy.

In example embodiments, a first overlay may be measured in the second direction using the first lower pattern 22 in the first region A1 and the first upper pattern 32 in the second region, both of which extend in the first direction. The first overlay in the second direction may be measured using a first lower non-overlapped zone D1 in the first region A1 and a first upper non-overlapped zone U1 in the second region A2. A second overlay may be measured in the first direction using the second upper pattern 34 in the first region A1 and the second lower pattern 24 in the second region, both of which extend in the second direction. The second overlay in the first direction may be measured using a second upper non-overlapped zone U2 in the first region A1 and a second lower non-overlapped zone D2 in the second region A2.

The first lower non-overlapped zone D1 in the first region A1 may include portions of the first lower pattern 22 that do not overlap with second upper pattern 34, and a non-patterned portion 50. The non-patterned portion 50 is the portion of first region A1 and second region A2 in which the lower pattern 20 and the upper pattern 30 are not formed. Particularly, the first lower non-overlapped zone D1 in the first region A1 may include a plurality of the first lower non-overlapped portions 22b and a plurality of the non-patterned portions 50 alternately arranged in the second direction. Thus, the first lower non-overlapped zone D1 may extend in the second direction. A plurality of the first lower non-overlapped zones D1 may be spaced apart from each other, along the first direction by a gap or pitch, which may be substantially the same as a width of the second upper pattern 34.

The second lower non-overlapped zone D2 in the second region A2 may include portions of the second lower pattern 24 that do not overlap with first upper pattern 32, and a non-patterned portion 50. Particularly, the second lower non-overlapped zone D2 in the second region A2 may include a plurality of the second lower non-overlapped portions 24b and a plurality of the non-patterned portions 50, alternately arranged in the first direction. The second lower non-overlapped zone D2 may extend in the first direction. A plurality of the second lower non-overlapped zones D2 may be spaced apart from each other, along the second direction by a gap or pitch, which may be substantially the same as a width of the first upper pattern 32.

The second upper non-overlapped zone U2 in the first region A1 may include portions of the second upper pattern 34 that do not overlap with first lower pattern 22 and a non-patterned portion 50. Particularly, the second upper non-overlapped zone U2 in the first region A1 may include a plurality of the second upper non-overlapped portions 34b and a plurality of the non-patterned portions 50 alternately arranged in the first direction, and so the second upper non-overlapped zone U2 may extend in the first direction. A plurality of the second upper non-overlapped zones U2 may be spaced apart from each other by a gap or pitch, which may be substantially the same as the width of the first lower pattern 22, along the second direction.

The first upper non-overlapped zone U1 in the second region A2 may include portions of the first upper pattern 32 that do not overlap with the second lower pattern 24, and a non-patterned portion 50. Particularly, the first upper non-overlapped zone U1 in the second region A2 may include a plurality of the first upper non-overlapped portions 32b and a plurality of the non-patterned portions 50 alternately arranged in the second direction. The first upper non-overlapped zone U1 may extend in the second direction. A plurality of the first upper non-overlapped zones U1 may be spaced apart from each other by a gap or pitch, which may be substantially the same as the width of the second lower pattern 24, along the first direction.

Although the first and second overlapped portions 42 and 44 may be formed in the first and second regions A1 and A2, the overlay may be stably measured using the image information obtained from the first lower and upper non-overlapped zones D1 and U1 and the second lower and upper non-overlapped zones D2 and U2. That is, the overlay may be stably measured using the non-overlapped zones D1, U1, D2 and U2 together with the overlapped portions.

In example embodiments, a length or a total area of the non-overlapped portions 22b, 24b, 32b and 34b in the lower pattern 20 or the upper pattern 30 respectively may be longer or larger than a length or a total area of the overlapped portion 40, i.e., 22a, 24a, 32a and 34a. The length may be a distance on an extending direction of the lower pattern 20 or the upper pattern 30.

The longer length of the non-overlapped portion 22b, 24b, 32b and 34b compared with the overlapped portion 40 may mean that a total length of the non-overlapped portions 22b, 24b, 32b and 34b may be longer than a total length of the overlapped portion 40 or a maximum length of the non-overlapped portions 22b, 24b, 32b and 34b may be longer than a maximum length of the overlapped portion 40.

A variety of comparisons can be used to measure overlay in the following examples. In one first lower pattern 22, a total length of the first lower non-overlapped portions 22b in the first direction may be longer than a total length of the first lower overlapped portions 22a. A maximum length of one first lower non-overlapped portion 22b in the first direction may be longer than a maximum length of one first lower overlapped portions 22a. In one second lower pattern 24, a total length of the second lower non-overlapped portions 24b in the second direction may be longer than a total length of the second lower overlapped portions 24a. A maximum length of one second lower non-overlapped portion 24b in the second direction may be longer than a maximum length of one second lower overlapped portion 24a.

In additional examples, in one first upper pattern 32, a total length of the first upper non-overlapped portions 32b in the first direction may be longer than a total length of the first upper overlapped portions 32a. A maximum length of one first upper non-overlapped portion 32b in the first direction may be longer than a maximum length of one first upper overlapped portion 32a. In one second upper pattern 34, a total length of the second upper non-overlapped portions 34b in the second direction may be longer than a total length of the second upper overlapped portions 34a. A maximum length of one second upper non-overlapped portion 34b in the second direction may be longer than a maximum length of one second upper overlapped portion 34a.

In further examples, a total area of the first lower non-overlapped portions 22b may be larger than a total area of the first lower overlapped portions 22a. A total area of the second lower non-overlapped portion 24b may be larger than a total area of the second lower overlapped portion 24a. A total area of the first upper non-overlapped portion 32b may be larger than a total area of the first upper overlapped portion 32a. A total area of the second upper non-overlapped portion 34b may be larger than a total area of the second upper overlapped portion 34a.

In addition, the lengths or the total areas of the first and second lower non-overlapped portions 22b and 32b and the first and second upper non-overlapped portions 24b and 34b may be designed to increase a total area of the non-overlapped zones D1, D2, U1 and U2, the overlay of which may be measured.

However, embodiments need not be restricted within the lengths or the total areas of the non-overlapped portions 22b, 24b, 32b and 34b and the overlapped portion 40. Although the lengths or the total areas of the first lower non-overlapped portion 22b, the second lower non-overlapped portion 24b, the first upper non-overlapped portion 32b and/or the second upper non-overlapped portion 34b may be relatively short or small, the overlay may be measured using corresponding portions. Further, the overlapped portion as well as the non-overlapped portion may be used for the overlay measuring. When the lower pattern 20 or the upper pattern 30 with the overlapped portion may be recognized, a correction value may be applied to the overlapped portion to measure the overlay.

Therefore, the length or the total area of the non-overlapped portions 22b, 24b, 32b and 34b in the lower pattern or the upper pattern 30 may be shorter or smaller than the length or the total area of the overlapped portion 40.

According to example embodiments, the lower pattern 20 and the upper pattern 30 in the image based overlay mark 10 may be arranged in the first region A1 and the second region A1 having the different pattern arrangements. Thus, the overlay mark 10 may have uniformly high pattern density in the total region to effectively prevent process errors such as erosion, dishing, etc., generated in the processes performed after forming the lower pattern 20. Further, the numbers of the patterns used for the overlay measuring may be increased. As a result, the errors of the overlay measuring generated by the process errors or by the lack of the pattern in numbers or total area may be minimized to improve the accuracy of the overlay measuring.

In FIG. 1, the first region A1 and the second region may be arranged to be adjacent to each other in the first direction. The first region A1 (left portion in FIG. 1) may have a shape extending in the second direction and the second region A2 (right portion in FIG. 1) may have a shape extending in the second direction. For example, the first region A1 and the second region A2 may be positioned adjacent to each other to have a square shape, thereby minimizing an area of the overlay mark 10.

The single first region A1 may be provided in the first direction and the single second region A2 may be provided in the first direction. Thus, the overlay mark 10 may include one block B including the first region A1 and the second region A2. As a result, the overlay mark 10 may have a simple planar shape to simplify a fabrication process, although other embodiments not limited thereto.

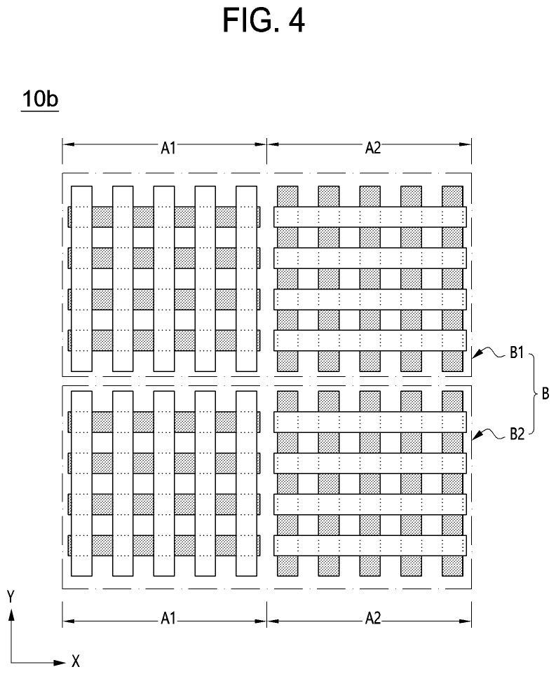

FIG. 4 is a plan view illustrating an image based overlay mark in accordance with example embodiments of the disclosure.

Referring to FIG. 4, an overlay mark 10b may include a plurality of blocks B1 and B2 arranged in the second direction. The block B may include a first block B1 and a second block B2, but other embodiments are not limited thereto. For example, the block B may include at least three blocks. The first region A1 in the first block B1 and the second block B2 may be positioned at one side (left portion in FIG. 4), spaced apart respectively in the first direction from second region A2 in the first block B1 and the second block B2 (right portion in FIG. 4), but other embodiments are not limited thereto.

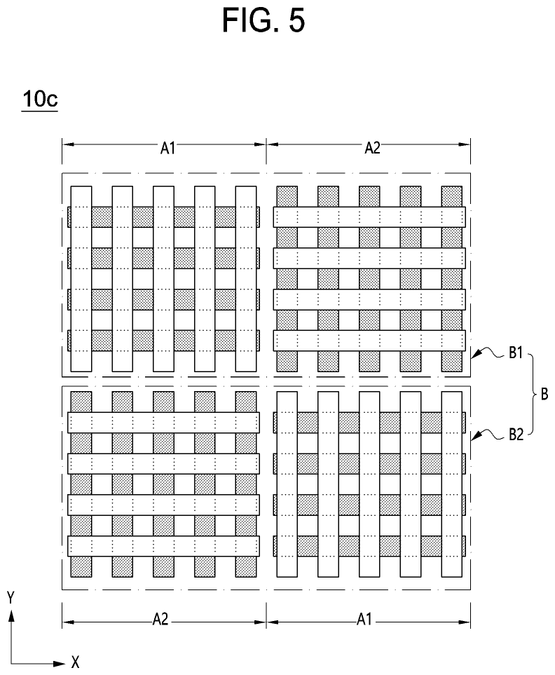

FIG. 5 is a plan view illustrating an image based overlay mark in accordance with example embodiments of the disclosure.

Referring to FIG. 5, compared to FIG. 4, the positions of the first region A1 and second region A2 in the second block B2 of an overlay mark 10c may be reversed. A plurality of the blocks B1 and B2 may be arranged in the second direction. A plurality of blocks B may be arranged in the first direction.

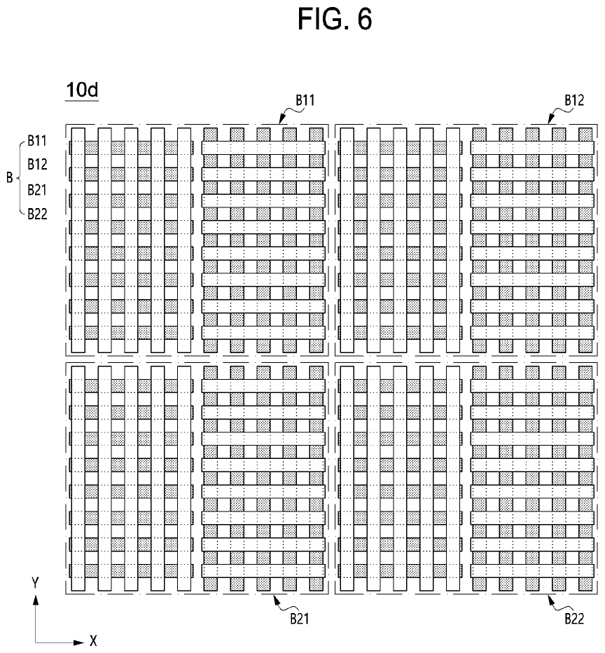

FIG. 6 is a plan view illustrating an image based overlay mark in accordance with example embodiments of the disclosure.

Referring to FIG. 6, an overlay mark 10d may include a plurality of blocks B arranged in the first and second directions. The block B may include two sub-blocks B11, B12 arranged in the first direction, and two sub-blocks B21 and B22 arranged in the first direction. Sub-blocks B11 and B21 may be arranged in the second direction, and sub-blocks B12 and B22 may be arranged in the second direction, although other embodiments are not limited thereto. The blocks B may be a matrix of sub-blocks, at least three in the first direction or the second direction. In the sub-blocks B11, B12, B21 and B22, the first region A1 may be positioned at one side in the first direction and the second region A2 may be positioned at the other side in the first direction, but other embodiments are not limited thereto. The arrangements of the first region A1 and the second region A2 in each of the sub-blocks B may be variously changed.

According to example embodiments, at least one block B may be provided in at least one of the first and second directions. When the first region A1 and the second region A2 may include the blocks B, the lower pattern 20 and the upper pattern 30 may be divided into smaller patterns. The smaller patterns may then be redistributed at various positions to improve the accuracy of the overlay measuring.

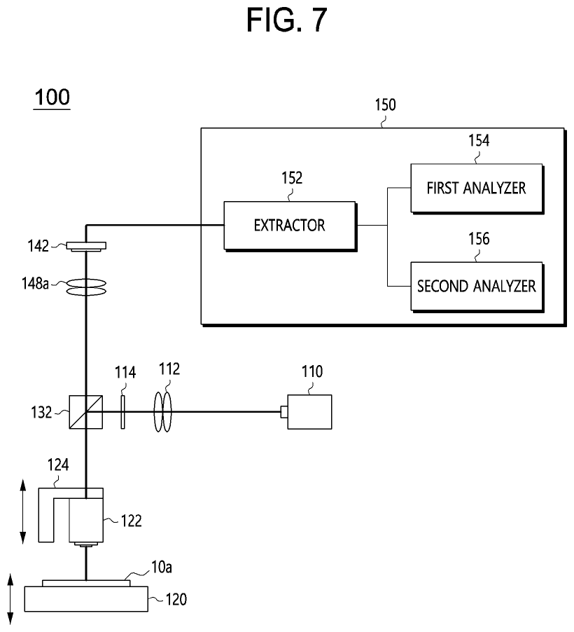

FIG. 7 is a view illustrating an image based overlay measuring apparatus configured to perform an image based overlay measuring method in accordance with example embodiments of the disclosure.

Referring to FIG. 7, an overlay measuring apparatus 100 may include a light source 110, a stage 120, an objective lens 122, a first beam splitter 132, a first detector 142 and a controller 150.

Examples of a light source 110 include a halogen lamp, a xenon lamp, a supercontinuum laser, a light emitting diode (LED), a laser induced lamp, etc. A light emitted from the light source 110 may be incident to the first beam splitter through the lens 112, a polarization plate 114, etc.

The first beam splitter 132 may split the beam emitted from the light source 110 through the lens 112 and the polarization plate 114 into two beams. That is, the first beam splitter 132 may pass a part of the beam emitted from the light source 110 therethrough. The first beam splitter 132 may reflect the rest of the beam to split the beam into the two beams.

The overlay mark 10 in FIG. 1, particularly, the structure 10a with the overlay mark 10, may be fixed to the stage 120. The objective lens 122 may be arranged between the structure 10a and the first beam splitter 132.

The objective lens 122 may concentrate the beam reflected from the first beam splitter 132 on a measurement spot of the structure 10a on the stage 120. The objective lens 122 may collect the beam reflected from the measurement spot. The objective lens 122 may be connected to a first driver 124. The first driver 124 may control a distance between the objective lens 122 and the structure 10a to locate a focusing face on the lower pattern 20 or the upper pattern 30, or between the lower pattern 20 and the upper pattern 30. The first driver 124 may include an actuator, but other embodiments are not limited thereto. Alternatively, the stage 120 may be moved in upward and downward directions to control the distance between the objective lens 122 and the structure 10a.

The first detector 142 may detect the beam collected by the objective lens 122. For example, a first tube lens 148a may be arranged between the first beam splitter 132 and the first detector 142. The first tube lens 148a may focus the image information on the first detector 142.

The first detector 142 may include a charge-coupled device (CCD) camera. The first detector 142 may obtain the image information. The first detector 142 may convert the image information into an electrical signal to generate an overlay signal. The overlay signal may be transmitted to the controller 150. The controller 150 may measure the overlay. In example embodiments, the first detector 142 may generate the overlay signal, but other embodiments are not limited thereto. Alternatively, when the first detector 142 provides the controller 150 with the image information, the controller 150 may generate the overlay signal. Further, when the detector 142 provides an operation controller of the overlay measuring apparatus 100 with the image information, the operation controller may generate the overlay signal.

As mentioned above, the overlay measuring method in accordance with a common focus process may be performed using the overlay measuring apparatus 100. In the common focus process, a lower overlay signal and an upper overlay signal may be generated using common image information, including the image information of the lower pattern 20 and the upper pattern 30. The lower overlay signal may include a first lower signal and a second lower signal. The upper overlay signal may include a first upper signal and a second upper signal.

The controller 150 may include an extractor 152, a first analyzer 154 and a second analyzer 156. The extractor 152 may extract the first lower signal and the first upper signal from among the first lower signal, the second lower signal, the first upper signal and the second upper signal. The extractor 152 may then transmit the first lower signal and the first upper signal to the first analyzer 154. The extractor 152 may extract the second lower signal and the second upper signal from among the first lower signal, the second lower signal, the first upper signal and the second upper signal. The extractor 152 may then transmit the second lower signal and the second upper signal to the second analyzer 156.

The first analyzer 154 may analyze and compare the first lower signal and the first upper signal with each other to measure the first overlay. The second analyzer 156 may analyze and compare the second lower signal and the second upper signal with each other to measure the second overlay. The first analyzer 154 and the second analyzer 156 may measure the first overlay and the second overlay using various analysis algorithms.

In FIG. 7, the controller 150 may be a separate device or part. Alternatively, the controller 150 may include software having various algorithms. Thus, the controller 150 may be provided to the operation controller of the overlay measuring apparatus 100 as hardware or software.

Hereinafter, an overlay measuring method using the overlay measuring apparatus may be illustrated with reference to FIGS. 1, 2, 7, 8 and 9.

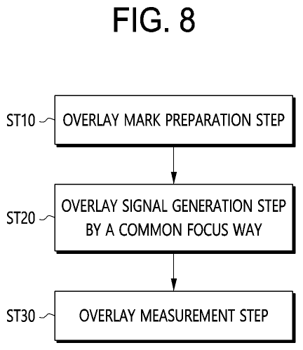

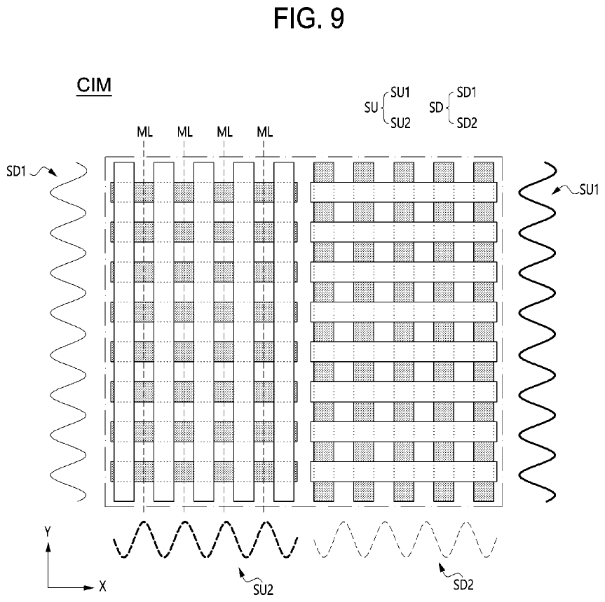

FIG. 8 is a flow chart illustrating an image based overlay measuring method in accordance with example embodiments of the disclosure. FIG. 9 is a view illustrating an overlay signal generation step in the image based overlay measuring method in FIG. 8. FIG. 9 may depict common image information and lower and upper overlay signals generated from the common image information.

Referring to FIGS. 1, 2, 7, 8 and 9, an overlay measuring method may include an overlay mark preparation step ST10, an overlay signal generation step ST20 and an overlay measuring step ST30. The overlay signal generation step ST20 may be performed by the common focus way, i.e., a common focus process.

In the overlay mark preparation step ST10, the overlay mark 10 may be prepared on the stage 120. Particularly, the structure 10a with the overlay mark 10 may be arranged on the stage 120.

The first driver 124 and/or the stage 120 may be driven to control the distance between the structure 10a and the objective lens 122, thereby focusing on the lower pattern 20, on the upper pattern 30, or in the lower pattern 20 and the upper pattern 30. In the common focus way, one common image information CIM with respect to the lower pattern 20 and the upper pattern 30 may be obtained.

The overlay may be measured from the common image information CIM. In order to precisely recognize the shapes of the lower pattern 20 and the upper pattern 30 on the common image information CIM, a focus may be focused between the lower pattern 20 and the upper pattern 30. For example, the focus may be focused on a middle spot between the lower pattern 20 and the upper pattern 30.

In the overlay signal generation step ST20, the first detector 142 may obtain the common image information CIM of the overlay mark 10. The first detector 142 may generate a lower overlay signal SD and an upper overlay signal SU from the common image information CIM. The lower overlay signal SD and the upper overlay signal SU may be generated by the first detector 142 or the controller 150.

For example, the common image information CIM may include a pixel image. In the pixel image, a portion where the lower pattern 20 and/or the upper pattern 30 may be positioned may be dark and another portion where the lower pattern 20 and/or the upper pattern 30 may not be positioned may be bright. The portion where the lower pattern 20 and/or the upper pattern 30 may be positioned may have result in a light intensity or brightness that is different from the light intensity or brightness of the portion where the lower pattern 20 and/or the upper pattern 30 is not positioned. Thus, a waveform, which may show changes of the light intensity or the brightness by position or location on the overlay mark 10, may be generated. The waveform may correspond to the lower overlay signal SD and the upper overlay signal SU. For example, the brightest portion of the lower overlay signal SD and the upper overlay signal SU may be represented by a peak. In contrast, the darkest portion of the lower overlay signal SD and the upper overlay signal SU may be represented by a valley, but embodiments of the disclosure are not limited thereto.

According to example embodiments, the lower overlay signal SD may be generated from a lower non-overlapped zones D1 and D2 of the lower pattern 20 using the common image information CIM of the overlay mark 10. The upper overlay signal SU may be generated from the upper non-overlapped zones U1 and U2 of the upper pattern 30 using the common image information CIM of the overlay mark 10.

As mentioned above, in the overlay mark 10 of example embodiments, the lower pattern 20 and the upper pattern 30 may be arranged in the first region A1. The lower pattern 20 and the upper pattern 30 may also be arranged in the second region A2. Thus, as shown in FIG. 9, in the overlay signal generation step ST20, the lower overlay signal SD may be generated from the first region A1 and the second region A2 and the upper overlay signal SU may be generated from the first region A1 and the second region A2. That is, the lower and upper overlay signals SD and SU may be generated from both the first region A1 and the second region A2.

Particularly, in the overlay signal generation step ST20, a first lower signal SD1 may be generated from the first lower non-overlapped zone D1. A second lower signal SD2 may be generated from the second lower non-overlapped zone D2. Further, a first upper signal SU1 may be generated from the first upper non-overlapped zone U1. A second upper signal SU2 may be generated from the second upper non-overlapped zone U2. The overlay signal generations may be different from the conventional art, where the lower overlay signal may be generated from only one of the first and second regions and the upper overlay signal may be generated from only one of the first and second regions.

FIG. 9 illustrates the lower overlay signal SD and the upper overlay signal SU respectively corresponding to the lower pattern 20 and the upper pattern 30 at edge portions of the overlay mark 10 x. With respect to the first lower and upper signals SD1 and SU1, waveform peaks may be located at the right portion or side (i.e., peaks in the positive X-direction). In the opposite direction (i.e., valleys in the negative X-direction), the valleys may be located at a left portion or side of the first lower and upper signals SD1 and SU1. With respect to the second lower and upper signals SD2 and SU2, the waveform peaks may be located at an upper portion (i.e., peaks in the positive Y-direction) and the valleys may be located at a lower portion in the opposite direction (i.e., valleys in the negative Y-direction).

The lower overlay signal SD or the upper overlay signal SU may be generated using an average or a sum of the light intensities in the lower non-overlapped zones D1 and D2 or the upper non-overlapped zones U1 and U2. The lower overlay signal SD or the upper overlay signal SU may be generated using an average or a sum of the light intensities in the total area of the lower non-overlapped zones D1 and D2 or the upper non-overlapped zone U1 and U2. Alternatively, the lower overlay signal SD or the upper overlay signal SU may be generated using an average or a sum of the light intensities in a plurality of measurement lines ML passing through the lower non-overlapped zones D1 and D2 or the upper non-overlapped zones U1 and U2.

For example, the average of the light intensities in the total area of the first lower non-overlapped zone D1 may be obtained to generate the first lower signal SD1. Alternatively, the sum of the light intensities in the total area of the first lower non-overlapped zone D1 may be obtained to generate the first lower signal SD1. Further, after generating signals from the measurement lines ML passing through the first lower non-overlapped zone D1, the first lower signal SD1 may be generated based on an average or a sum of the signals. The measurement lines ML may be extended parallel to each other between the second upper patterns 34. For example, the measurement lines ML may pass through a middle region between the first lower non-overlapped zones D1, but other embodiments are not limited thereto.

In example embodiments, in order to improve accuracy, the overlay signals SD and SU may be generated based on the total area of the non-overlapped zones D1, D2, U1 and U2 or the measurement lines ML, but other embodiments are not limited thereto. For example, in other embodiments the overlay signals SD and SU may be generated based on one measurement line ML.

In example embodiments, the lower overlay signal SD or the upper overlay signal SU may be generated using the lower non-overlapped zones D1 and D2 or the upper non-overlapped zones U1 and U2. Alternatively, the lower overlay signal SD or the upper overlay signal SU may be generated using the image information of the overlapped region, including the overlapped portion 40. That is, the lower overlay signal SD may be generated using the image information of a region as the overlapped zone where the upper pattern 30 may be formed. The upper overlay signal SU may be generated using the image information of a region as the overlapped zone where the lower pattern 20 may be formed. For example, when the light intensity or the brightness in the overlapped zone cannot be recognized, a result value may not be affected by reflecting a value of the overlapped zone. Further, when the light intensity or the brightness in the overlapped zone can be recognized, the result value may not be greatly affected by reflecting the value of the overlapped zone. When the value of the overlapped zone might not be accurate, the value of the overlapped zone as a corrected value or a converted value may be used.

That is, the lower overlay signal SD or the upper overlay signal SU may be generated using the overlapped zone as well as the lower non-overlapped zones D1 and D2 or the upper non-overlapped zones U1 and U2.

In the overlay measurement step ST30, the lower overlay signal SD and the upper overlay signal SU may be analyzed to measure the overlay. For example, positions of the peaks or the valleys in the lower overlay signal SD and the upper overlay signal SU may be compared with each other to measure warpage or misalignment between the lower pattern 20 and the upper pattern 30.

Particularly, the extractor 152 of the controller 150 may extract the first lower signal SD1 and the first upper signal SU1 from among the first and second lower signals SD1 and SD2 and the first and second upper signals SU1 and SU2. The extractor 152 may then transmit the first lower signal SD1 and the first upper signal SU1 to the first analyzer 154. The extractor 152 may extract the second lower signal SD2 and the second upper signal SU2 from among the first and second lower signals SD1 and SD2 and the first and second upper signals SU1 and SU2. The extractor 152 may then transmit the second lower signal SD2 and the second upper signal SU2 to the second analyzer 156.

The first analyzer 154 may analyze the first lower signal SD1 and the first upper signal SU1 to measure the first overlay in the second direction. The second analyzer 156 may analyze the second lower signal SD2 and the second upper signal SU2 to measure the second overlay in the first direction.

In the common focus way, after obtaining the common image information CIM, the first and second lower signals SD1 and SD2 and the first and second upper signals SU1 and SU2 may be generated from the common image information CIM. The first and second lower signals SD1 and SD2 and the first and second upper signals SU1 and SU2 may be extracted and compared with each other to measure the overlay.

In example embodiments, the first region A1 and the second region A2 may be positioned adjacent to each other. As described above, the second lower pattern 24 and the second upper pattern 34 may be arranged to be spaced apart from each other by a second pitch to provide the second lower pattern 24 and the second upper pattern 34 with a continuous period, so that the distance between the first region A1 and the second region A2 may be substantially equal to or less than the second pitch P2. Thus, the image information may be obtained from the overlay mark 10 having a smaller area without an additional process. The overlay signals SD and SU may then be obtained to measure the overlay. That is, an additional process such as a rotation process, or an additional apparatus such as a phase converter configured to form or maintain the offset used in the diffraction based overlay measuring, may not be required in disclosed embodiments, so the process and the apparatus may be simplified.

When the image based overlay marks 10 have an overlapped portion 40, the lower overlay signal SD and the upper overlay signal SU may be stably generated using the lower non-overlapped zones D1 and D2 and the upper non-overlapped zones U1 and U2 to measure the first and second overlays. Thus, although the lower pattern 20 and the upper pattern 30, which form the overlapped portion 40, can increase the pattern density, the overlay may be accurately measured using the non-overlapped zones D1, D2, U1 and U2. The process may be simplified using the common image information CIM to reduce process time.

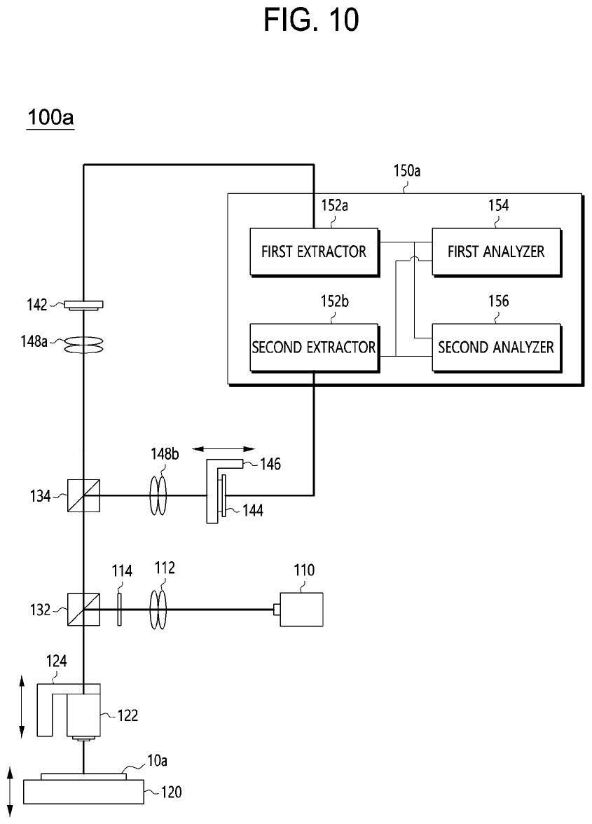

FIG. 10 is a view illustrating an image based overlay measuring apparatus configured to perform an image based overlay measuring method in accordance with example embodiments of the disclosure.

Referring to FIG. 10, an overlay measuring apparatus 100a may include a light source 110, a stage 120, an objective lens 122, first and second drivers 124 and 146, first and second beam splitters 132 and 134, first and second detectors 142 and 144 and a controller 150a.

The light source 110, the stage 120, the objective lens 122, the first driver 124, the first beam splitter 132, the first tube lens 148a and the first detector 142 of the overlay measuring apparatus 100a in FIG. 10 may be substantially the same as the light source 110, the stage 120, the objective lens 122, the first driver 124, the first beam splitter 132, the first tube lens 148a and the first detector 142 of the overlay measuring apparatus 100 in FIG. 7, respectively. Thus, any further description with respect to the same elements may be omitted herein for brevity.

The beam collected by the objective lens 122 may be incident to the second beam splitter 134 through the first beam splitter 132. The second beam splitter 134 may split the beam into two beams. That is, the beam incident to the second beam splitter 134 may be split into a first beam used for detecting any one of the lower pattern 20 and the upper pattern 30 and a second beam used for detecting the remaining one of the lower pattern 20 and the upper pattern 30.

The first detector 142 may detect the first beam passing through the second beam splitter 134. The second detector 144 may detect the second beam reflected from the second beam splitter 134. The second detector 144 may be installed at the second driver 146. The second driver 146 may control a distance between the second beam splitter 134 and the second detector 144. The second driver 146 may include an actuator, but other embodiments are not limited thereto.

The first detector 142 may obtain first image information focused on one of the lower pattern 20 and the upper pattern 30 to generate the first overlay signal from the first image information. The second detector 144 may obtain second image information focused on the other one of the lower pattern 20 and the upper pattern 30 to generate the second overlay signal from the second image information. Thus, the first overlay signal may correspond to one of the lower overlay signal or the upper overlay signal, and the second overlay signal may correspond to the other of lower overlay signal or the upper overlay signal. Hereinafter, the first image information obtained by the first detector 142 may correspond to the lower image information. The second image information obtained by the second detector 144 may correspond to the upper image information, but other embodiments are not limited thereto. For example, the first image information may correspond to the upper image information and the second image information may correspond to the lower image information.

The second detector 144 may include a charge-coupled device (CCD) camera, but other embodiments are not limited thereto.

In example embodiments, the distance between the objective lens 122 and the structure 10a with the overlay mark 10 may be controlled to position a focus face at any one of the lower pattern 20 and the upper pattern 30. In order to obtain a clean image of the other one of the lower pattern 20 and the upper pattern 30, the second driver 146 may control a distance between the second detector 144 and the second beam splitter 134, taking into consideration the height difference between the lower pattern 20 and the upper pattern 30.

First and second tube lenses 148a and 148b may be arranged respectively between the second beam splitter 134 and the first detector 142 and between the second beam splitter 134 and the second driver 146 with the second detector 144. The first and second tube lenses 148a and 148b may focus the first image information and the second image information on the first detector 142 and the second detector 144, respectively.

As described above, the overlay measuring method may be performed using the overlay measuring apparatus 100a by the dual focus way. In the dual focus way, the lower overlay signal may be generated using the lower image information obtained when the focus is focused on the lower pattern 20. The upper overlay signal may be generated using the upper image information obtained when the focus is focused on the upper pattern 30. The lower overlay signal may include the first lower signal and the second lower signal. The upper overlay signal may include the first upper signal and the second upper signal.

The controller 150a may include first and second extractors 152a and 152b, a first analyzer 154 and a second analyzer 156. The first extractor 152a may extract the first and second lower signals from the lower overlay signal generated from the lower image information. The first extractor 152a may then transmit the first lower signal and the second lower signal to the first analyzer 154 and the second analyzer 156, respectively. The second extractor 152b may extract the first and second upper signals from the upper overlay signal generated from the upper image information. The second extractor 152b may then transmit the first upper signal and the second upper signal to the first analyzer 154 and the second analyzer 156, respectively.

The first analyzer 154 may analyze and compare the first lower signal and the first upper signal with each other to measure the first overlay. The second analyzer 156 may analyze and compare the second lower signal and the second upper signal with each other to measure the second overlay.

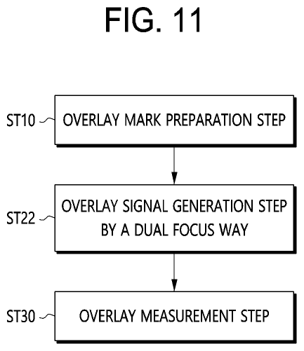

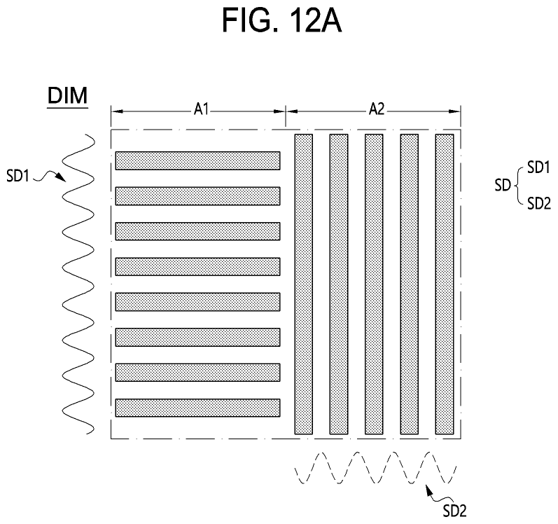

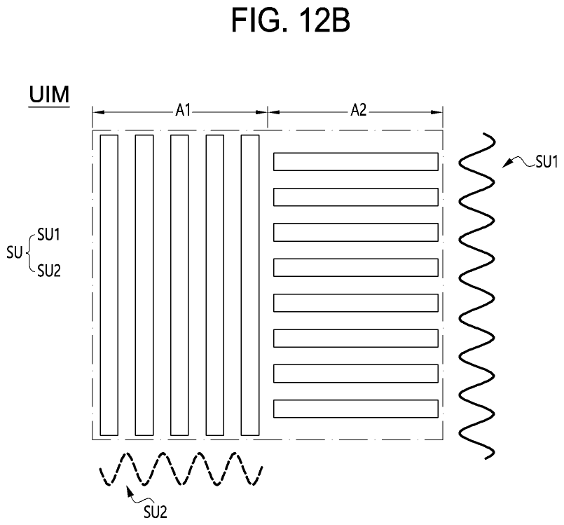

FIG. 11 is a flow chart illustrating an image based overlay measuring method in accordance with example embodiments of the disclosure. FIGS. 12A and 12B are a view illustrating an overlay signal generation step in the image based overlay measuring method in FIG. 11. FIG. 12A may show the lower image information and the lower overlay signal generated from the lower image information. FIG. 12B may show the upper image information and lower and the upper overlay signal generated from the upper image information.

Referring to FIGS. 1, 2, 10, 11, 12A and 12B, an overlay measuring method may include an overlay mark preparation step ST10, an overlay signal generation step ST22 and an overlay measurement step ST30. The overlay signal generation step ST22 may be performed by the dual focus way.

In the overlay mark preparation step ST10, the overlay mark 10 may be prepared on the stage 120. Particularly, the structure 10a with the overlay mark 10 may be arranged on the stage 120.

The first driver 124 and/or the stage 120 may be driven to control the distance between the structure 10a and the objective lens 122, thereby focusing on either one of the lower pattern 20 and the upper pattern 30. The second driver 146 may be driven to control the distance between the second beam splitter 134 and the second detector 144, thereby focusing on the other of the lower pattern 20 and the upper pattern 30.

In the overlay signal generation step ST22, the first detector 142 may obtain the first image information (upper or lower image information) when the focus is focused on either one of the lower pattern 20 and the upper pattern 30. The second detector 144 may obtain the second image information (upper or lower image information) when the focus is focused on the other of the lower pattern 20 and the upper pattern 30. The lower image information DIM and/or the upper image information UIM may include a pixel image.

In example embodiments, the first detector 142 may obtain the lower image information and the second detector 144 may obtain the upper image information.

As described above, in the overlay mark 10 of example embodiments, the lower pattern 20 and the upper pattern 30 may be arranged in the first region A1. The lower pattern 20 and the upper pattern 30 may also be arranged in the second region A2. Thus, as shown in FIG. 12A, the lower overlay signal SD may be generated from the first region A1 and the second region A2. Further, as shown in FIG. 12B, the upper overlay signal SU may be generated from the first region A1 and the second region A2. That is, the lower and upper overlay signals SD and SU may each be generated from the first region A1 and from the second region A2.

Particularly, in the overlay signal generation step ST22, the lower overlay signal SD may be generated using the lower image information DIM obtained when the lower pattern 20 is in focus. The upper overlay signal SU may be generated using the upper image information UIM obtained when the upper pattern 30 is in focus. For example, as shown in FIG. 12A, the first lower signal SD1 may be generated using the first lower pattern 22 in the first region A1. The second lower signal SD2 may be generated using the second lower pattern 24 in the second region A2. As shown in FIG. 12B, the second upper signal SU2 may be generated using the second upper pattern 34 in the first region A1. The first upper signal SU1 may be generated using the first upper pattern 32 in the second region A2.

FIGS. 12A and 12B illustrate the lower overlay signal SD and the upper overlay signal SU at edge portions of the overlay mark 10 corresponding to the lower pattern 20 and the upper pattern 30. The valley may be located at a left portion with respect to the first lower and upper signals SD1 and SU1 and the peak may be located at a right portion with respect to the first lower and upper signals SD1 and SU1. The valley may be located at a lower portion with respect to the second lower and upper signals SD2 and SU2 and the peak may be located at an upper portion with respect to the second lower and upper signals SD2 and SU2.

The lower overlay signal SD may be generated using only the lower non-overlapped zones D1 and D2. Alternatively, the lower overlay signal SD may be generated using the lower non-overlapped zones D1 and D2 and the overlapped zones (areas or regions except for the lower non-overlapped zone or a portion of the upper pattern 30). The upper overlay signal SU may be generated using only the upper non-overlapped zones U1 and U2. Alternatively, the upper overlay signal SU may be generated using the upper non-overlapped zones U1 and U2 and the overlapped zone (areas or regions except for the upper non-overlapped zone or a portion of the lower pattern 20). A value may be applied to the overlapped zone or a corrected or converted value may be applied to the overlapped zone.

In example embodiments, the lower image information DIM and the upper image information UIM may be independently obtained by the dual focus way. Thus, the lower pattern 20 may be clearly recognized on the lower image information DIM without interference of the upper pattern 30. The upper pattern 30 may be clearly recognized on the upper image information UIM without interference of the lower pattern 20. Thus, the lower overlay signal SD or the upper overlay signal SU may be generated using overlapping zones or areas.

When the lower overlay signal SD or the upper overlay signal SU is generated using only the non-overlapped zones D1, D2, U2 and U2, the lower overlay signal SD or the upper overlay signal SU may be generated using an average or a sum of the light intensities in the lower non-overlapped zones D1 and D2 or the upper non-overlapped zones U1 and U2. The lower overlay signal SD or the upper overlay signal SU may be generated using an average or a sum of the light intensities in the total area of the lower non-overlapped zones D1 and D2 or the upper non-overlapped zones U1 and U2. Alternatively, the lower overlay signal SD or the upper overlay signal SU may be generated using an average or a sum of the light intensities in a plurality of measurement lines ML passing through the lower non-overlapped zones D1 and D2 or the upper non-overlapped zones U1 and U2.

When the lower overlay signal SD or the upper overlay signal SU may be generated using the non-overlapped zones D1, D2, U2 and U2 and the overlapped zones, the lower overlay signal SD or the upper overlay signal SU may be generated using an average or a sum of the light intensities in the all regions. The lower overlay signal SD or the upper overlay signal SU may be generated using an average or a sum of the light intensities in the total area of the all regions. Alternatively, the lower overlay signal SD or the upper overlay signal SU may be generated using an average or a sum of the light intensities in a single or a plurality of measurement lines ML passing through the lower pattern 20 or the upper pattern 30.

In the overlay measuring step ST30, the lower overlay signal SD and the upper overlay signal SU may be analyzed to measure the overlay. For example, positions of the peaks or the valleys in the lower overlay signal SD and the upper overlay signal SU may be compared with each other to measure warpage or misalignment between the lower pattern 20 and the upper pattern 30.

Particularly, the first extractor 152a may extract the first lower signal SD1 from the first and second lower signals SD1 and SD2 generated from the lower image information. The first extractor 152a may then transmit the first lower signal SD1 to the first analyzer 154. The second extractor 152b may extract the first upper signal SU1 from the first and second upper signals SU1 and SU2 generated from the upper image information. The second extractor 152b may then transmit the first upper signal SU1 to the second analyzer 156.

The first analyzer 154 may analyze the first lower signal SD1 and the first upper signal SU1 to measure the first overlay in the second direction. The second analyzer 156 may analyze the second lower signal SD2 and the second upper signal SU2 to measure the second overlay in the first direction.

In the dual focus way, after independently obtaining the lower image information DIM and the upper image information UIM, the lower overlay signal SD may be generated from the lower image information DIM and the upper overlay signal SU may be generated from the upper image information UIM. Although the overlapped portion 40 may exist, the influence from the overlapped portion 40 may be minimized to improve the accuracy of the overlay measuring. Because the lower image information DIM and the upper image information UIM may be simultaneously obtained using the first detector 142 and the second detector 144, the overlay signal may be rapidly generated when the lower image information DIM and the upper image information UIM are collected together.

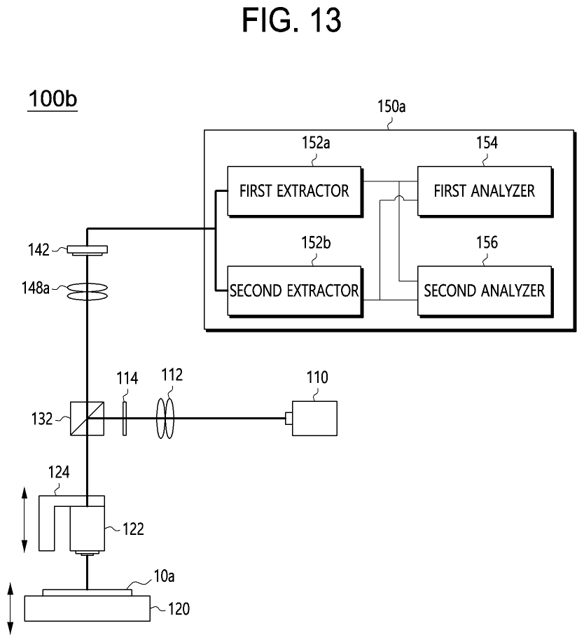

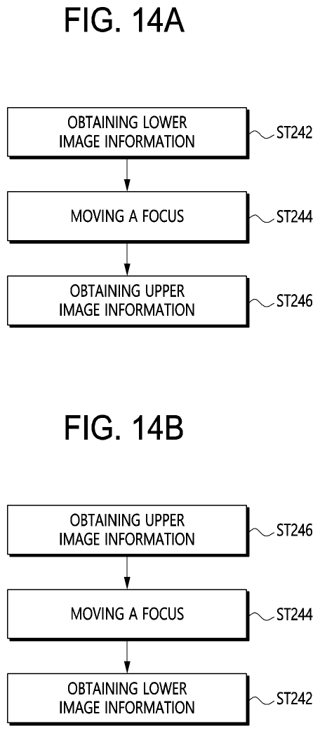

FIG. 13 is a view illustrating an image based overlay measuring apparatus configured to perform an image based overlay measuring method in accordance with example embodiments of the disclosure. FIGS. 14A and 14B are a flow chart illustrating an overlay signal generation step in an image based overlay measuring method in accordance with example embodiments of the disclosure.

Referring to FIG. 13, an overlay measuring apparatus 100b of example embodiments may be substantially the same as the overlay measuring 100 in FIG. 7, except for a controller 150a. The controller 150a may include first and second extractors 152a and 152b and first and second analyzers 154 and 156 of the overlay measuring apparatus 100a in FIG. 10. The first and second extractors 152a and 152b may be connected to the first detector 142. The first and second extractors 152a and 152b may receive the lower and upper image information from the first detector 142 or the lower and upper overlay signals generated from the lower and upper image information.

Referring to FIGS. 14A and 14B, an overlay measuring method of example embodiments may include an overlay mark preparation step, an overlay signal generation step ST24 and an overlay measurement step. The overlay mark preparation step and the overlay measurement step are substantially similar to the same steps in FIGS. 8 and 11. Thus, any further illustrations with respect to the same steps may be omitted herein for brevity.

FIG. 14A illustrates the overlay signal generation step ST24, which may include a lower image information obtaining step ST242, a focus movement step ST244 and an upper image information obtaining step ST246.

In the lower image information obtaining step ST242, the lower image information may be obtained by focusing on the lower pattern 20. In the focus movement step ST244, the focus may be moved from the lower pattern 20 to the upper pattern 30. The focus may be moved using the first driver 124 and/or the stage 120. In the upper image information obtaining step ST246, the upper image information may be obtained by focusing on the upper pattern 30.

The lower overlay signal may be generated from the lower image information. The upper overlay signal may be generated from the upper image information. The lower overlay signal and the upper overlay signal may be sequentially or simultaneously generated. The lower overlay signal may be generated from the first detector 142. The lower overlay signal may then be transmitted to the first extractor 152a. The lower image information may be transmitted to the first extractor 152a to generate the lower image information. The upper overlay signal may be generated from the first detector 142. The upper overlay signal may then be transmitted to the second extractor 152b. The upper image information may be transmitted to the second extractor 152b to generate the upper image information.

Alternatively, as shown in FIG. 14B, the overlay signal generation step ST24 may include an upper image information obtaining step ST246, a focus movement step ST244 and a lower image information obtaining step ST242. After obtaining the upper image information, the focus may be moved from the upper pattern 30 to the lower pattern 20. The lower image information may then be obtained.

According to example embodiments, by moving the focus, the second detector 144 and the second beam splitter 134 may not be required. Thus, the dual focus way may be performed using the overlay measuring apparatus 100b having the simpler or reduced structure.

FIG. 13 illustrates the first extractor 152a and the second extractor 152b, but other embodiments are not limited thereto. As shown in FIG. 7, the controller 150 may include only the extractor 152. In this case, the lower overlay signal and the upper overlay signal may be transmitted to the extractor 152. The extractor 152 may extract the first lower signal and the first upper signal. The extractor 152 may then transmit the first lower signal and the first upper signal to the first analyzer 154. The extractor 152 may extract the second lower signal and the second upper signal. The extractor 152 may then transmit the second lower signal and the second upper signal to the second analyzer 156.

The above described embodiments of the present disclosure are intended to illustrate and not to limit the present invention. Various alternatives and equivalents are possible. The invention is not limited by the embodiments described herein. Nor is the invention limited to any specific type of semiconductor device. Another additions, subtractions, or modifications are obvious in view of the present disclosure and are intended to fall within the scope of the appended claims.

What is claimed is:

1. An image based overlay measuring method comprising:
preparing at least one image based overlay mark, including at least one lower pattern and at least one upper pattern, having an overlapped portion between the lower pattern and the upper pattern from a plan view;
generating a lower overlay signal based on a lower non-overlapped zone of the lower pattern and an upper overlay signal based on an upper non-overlapped zone of the upper pattern using image information of the image based overlay mark; and
measuring an overlay of the image based overlay mark by comparing the lower overlay signal with the upper overlay signal to measure an overlay of the image based overlay mark.

2. The image based overlay measuring method of claim 1, wherein the image based overlay mark includes a plurality of overlay marks that are arranged in a first region and a second region adjacent to the first region, the overlay marks of the first region are arranged differently from the overlay marks of the second region,
wherein the lower overlay signal includes a first lower signal generated from the first region and a second lower signal generated from the second region, and the upper overlay signal includes a first upper signal generated from the second region and a second upper signal generated from the first region.

3. The image based overlay measuring method of claim 2, wherein the measuring the overlay of the image based overlay mark includes:
extracting and comparing the first lower signal and the first upper signal to measure a first overlay; and
extracting and comparing the second lower signal and the second upper signal to measure a second overlay.

4. The image based overlay measuring method of claim 2, wherein the lower pattern includes a plurality of first lower patterns extended in the first region along a first direction and a plurality of second lower patterns extended in the second region along a second direction intersected with the first direction, and
is the upper pattern includes a plurality of first upper patterns extended in the second region along the first direction and a plurality of second upper patterns extended in the first region along the second direction.

5. The image based overlay measuring method of claim 4, wherein the first lower signal and the second lower signal are generated using the first lower patterns and the second lower patterns, and the first upper signal and the second upper signal are generated using the first upper patterns and the second upper patterns.

6. The image based overlay measuring method of claim 1, wherein the generating a lower overlay signal and the upper overlay signal includes: generating at least one of the lower overlay signal and the upper overlay signal using at least one of an average and a sum of a light intensity in at least one of the lower non-overlapped zone and the upper non-overlapped zone.

7. The image based overlay measuring method of claim 6, wherein the generating a lower overlay signal and the upper overlay signal includes generating at least one of the lower overlay signal and the upper overlay signal based on a value related to a light intensity to at least one of a total area and a measurement line,
wherein the value is at least one of an average of the light intensity to the total area and the measurement line and a sum of the light intensity to the total area and the measurement line, and
wherein the total area includes the lower non-overlapped zone and the upper non-overlapped zone, and the measurement line is a line that, in a plan view, passes through the lower non-overlapped zone and the upper non-overlapped zone.

8. The image based overlay measuring method of claim 1, wherein the lower overlay signal is generated using lower image information obtained when the lower pattern is in focus and the upper overlay signal is generated using upper image information obtained when the upper pattern is in focus.

9. The image based overlay measuring method of claim 8, wherein the generating a lower overlay signal and the upper overlay signal includes: moving a focus from the upper pattern to the lower pattern or the lower pattern to the upper pattern, and
wherein the lower image information is detected by a first detector and the upper image information is detected by a second detector.

10. The image based overlay measuring method of claim 1, wherein the lower overlay signal and the upper overlay signal are generated using common image information obtained when the lower pattern, the upper pattern or a portion between the lower pattern and the upper pattern is in focus.

11. The image based overlay measuring method of claim 1, wherein at least one of the lower pattern and the upper pattern further includes a non-overlapped portion,
wherein at least one of a length and an area of the non-overlapped portion of the lower pattern and the upper pattern is greater than at least one of a length and an area of the overlapped portion of the lower pattern and the upper pattern.

12. The image based overlay measuring method of claim 1, wherein at least one of the lower overlay signal and the upper overlay signal is generated using the image information of an overlapped zone with the overlapped portion.

13. An image based overlay measuring method comprising:
preparing an image based overlay mark including a lower pattern and an upper pattern having an overlapped portion from a plan view;
generating a lower overlay signal using lower image information when the lower pattern is in focus and an upper overlay signal using upper image information when the upper pattern is in focus; and
measuring an overlay of the image based overlay mark by comparing the lower overlay signal with the upper overlay signal to measure an overlay of the image based overlay mark.

14. The image based overlay measuring method of claim 13, wherein the image based overlay mark includes a plurality of overlay marks arranged in a first region and a second region adjacent to the first region, the overlay marks of the first region are arranged differently from the overlay marks of the second region,
wherein the lower overlay signal includes a first lower signal generated from the first region and a second lower signal generated from the second region, and the upper overlay signal includes a first upper signal generated from the second region and a second upper signal generated from the first region, and
wherein the first lower signal and the first upper signal are extracted and compared with each other to measure a first overlay and the second lower signal and the second upper signal are extracted and compared with each other to measure a second overlay.

15. The image based overlay measuring method of claim 13, wherein at least one of the lower overlay signal and the upper overlay signal is generated using at least one of the non-overlapped zone, and the non-overlapped zone and an overlapped zone.

16. The image based overlay measuring method of claim 13, wherein the overlay signal generation step comprises moving a focus from the upper pattern to the lower pattern or the lower pattern to the upper pattern, or
the overlay signal generation step comprises using a first detector configured to detect lower image information when focused on the lower pattern and a second detector configured to detect upper image information when focused on the upper pattern.

17. An image based overlay mark used for measuring an overlay using image information, the image based overlay mark comprising:
a lower pattern including a plurality of first lower patterns extending in a first region along a first direction, and a plurality of second lower patterns extending in a second region along a second direction intersected with the first direction; and
an upper pattern including a plurality of first upper patterns extending in the second region along the first direction, and a plurality of second upper patterns extending in the first region along the second direction, the upper pattern being arranged over the lower pattern to partially overlap the lower pattern.

18. The image based overlay mark of claim 17, wherein the first upper patterns and the second lower patterns are spaced apart from each other by a first pitch, and
the first lower patterns and the second upper patterns are spaced apart from each other by a second pitch from a plan view.

19. The image based overlay mark of claim 17, wherein each of the lower pattern and the upper pattern includes at least one non-overlapped portion and at least one overlapped portion between the lower pattern and the upper pattern, and at least one of a length and an area of the non-overlapped portion is greater than at least one of a length and an area of the overlapped portion.

20. The image based overlay mark of claim 17, wherein a plurality of blocks including the first region and the second region are arranged in at least one of the first direction and the second direction.
